(19) United States
(12) Patent Application Publication
(10) Pub. No.: US 2025/0318131 A1
(43) Pub. Date: Oct. 9, 2025

(54) FLASH MEMORY AND METHODS FOR MANUFACTURING THE SAME

(71) Applicant: Winbond Electronics Corp., Taichung City (TW)

(72) Inventor: Chung-Hsien LIU, Taichung City (TW)

(21) Appl. No.: 19/169,296

(22) Filed: Apr. 3, 2025

(30) Foreign Application Priority Data
Apr. 9, 2024 (TW) 113113104

(51) Int. Cl. H10B 43/30; G11C 16/04; H10B 41/10; H10B 41/20; H10B 41/30; H10B 43/10; H10B 43/20

(52) U.S. Cl. CPC H10B 43/30; G11C 16/0483; H10B 41/10; H10B 41/20; H10B 41/30; H10B 43/10; H10B 43/20

(57) ABSTRACT

A flash memory includes a substrate having several active regions and several memory cells. Each of the memory cells includes a lower gate electrode, an inter-gate dielectric layer on the lower gate electrode and an upper gate electrode on the inter-gate dielectric layer. The lower gate electrode includes a first portion over the substrate and a second portion inserted into the first portion. The first portion surrounds the lower part of the second portion. The upper part of the second portion protrudes from the top surface of the first portion. The inter-gate dielectric layer covers the top surface and side surfaces of the upper part. The first portion and the second portion include different materials.

### CROSS REFERENCE TO RELATED APPLICATIONS

This application claims priority of Taiwan Patent Application No. 113113104, filed on Apr. 9, 2024, the entirety of which is incorporated by reference herein.

### BACKGROUND

### Technical Field

The disclosure relates to a flash memory and methods for manufacturing the same, and it relates to a flash memory that can increase the gate coupling ratio and improve the electrical performance, and methods for manufacturing the same.

### Description of the Related Art

As semiconductor manufacturing technology continues to develop toward the miniaturization of components, many challenges arise. In the case of flash memory, for example, the miniaturization of component sizes has led to reduced distance between memory word lines, resulting in a lower gate coupling ratio and increased interference, which in turn affects the electrical performance and the reliability of the memory devices. Therefore, existing memory devices and their manufacturing methods still have problems that need to be overcome.

### SUMMARY

The flash memory and the manufacturing method thereof, as provided in the present disclosure, can solve the problem of the reduced gate coupling ratio that is caused by miniaturizing the size of the device, thereby improving the electrical performance and reliability of the flash memory.

Some embodiments of the present disclosure provide a flash memory that includes a substrate and several memory cells. The substrate has several active regions. Each of the memory cells includes a lower gate electrode, an inter-gate dielectric layer on the lower gate electrode and an upper gate electrode on the inter-gate dielectric layer. The lower gate electrode includes a first portion over the substrate and a second portion that is inserted into the first portion. The first portion surrounds the lower part of the second portion, wherein the first portion and the second portion include different materials. The upper part of the second portion protrudes from the top surface of the first portion, and the inter-gate dielectric layer covers the top surface and the sidewalls of the upper part of the second portion.

Some embodiments of the present disclosure provide a method for manufacturing a flash memory. The method includes providing a substrate that has active regions and forming several memory cells. Each of the memory cells includes a lower gate electrode, an inter-gate dielectric layer formed on the lower gate electrode and an upper gate electrode formed on the inter-gate dielectric layer. Forming the lower gate electrode includes forming a first portion over the substrate and forming a second portion that is inserted into the first portion. The first portion surrounds the lower part of the second portion, and the upper part of the second portion protrudes from the top surface of the first portion. The inter-gate dielectric layer covers the top surface and the sidewalls of the upper part of the second portion. In addition, the first portion and the second portion include different materials.

According to the flash memory and the manufacturing method thereof as provided in some embodiments of the present disclosure, the lower gate electrode of the flash memory has a dual-structure and includes a protruding portion, so as to increase the contact area between the inter-gate dielectric layer and the lower gate electrode, thereby increasing the gate coupling ratio and increasing the reliability of the memory cells. Accordingly, the electrical performance of the flash memory can be improved.

### BRIEF DESCRIPTION OF THE DRAWINGS

FIG. 1A, FIG. 1B, FIG. 2A, FIG. 2B, FIG. 3A-FIG. 3D, FIG. 4, FIG. 5A, FIG. 5B, FIG. 6, FIG. 7, FIG. 8, FIG. 9A and FIG. 9B illustrate various intermediate stages for manufacturing a flash memory, in accordance with some embodiments of the present disclosure,
wherein FIG. 1A, FIG. 2A, FIG. 5A and FIG. 9A are fragmentary top views of a flash memory that includes memory cells in active regions at various intermediate manufacturing stages, in accordance with some embodiments of the present disclosure; and

FIG. 1B, FIG. 2B, FIG. 5B and FIG. 9B are schematic cross-sectional views taken along line 1B-1B, line 2B-2B, line 5B-5B and line 9B-9B of the structures of FIG. 1A, FIG. 2A, FIG. 5A and FIG. 9A, respectively.

FIG. 10 is a three-dimensional schematic diagram of a flash memory, in accordance with some embodiments of the present disclosure.

FIG. 11 is a schematic cross-sectional view taken along line L1-L1 of a flash memory of FIG. 9A, in accordance with some embodiments of the present disclosure. It is noted that line L1-L1 cuts a position outside the second portion of the lower gate electrode.

FIG. 12 is a schematic cross-sectional view taken along line L2-L2 of a flash memory of FIG. 9A, in accordance with some embodiments of the present disclosure. It is noted that line L2-L2 cuts a position corresponding to the second portion of the lower gate electrode.

FIG. 13 illustrates a schematic cross-sectional view of a conventional flash memory.

FIG. 14A shows Gaussian distribution curves of the threshold voltages of a conventional flash memory.

FIG. 14B shows Gaussian distribution curves of the threshold voltages of a flash memory, in accordance with some embodiments of the present disclosure.

### DETAILED DESCRIPTION

The following contents provide different embodiments or examples for implementing different features of the provided subject matter. These are, of course, only examples and are not intended to limit the disclosure. In addition, unless specifically defined, the formation of a first feature over or on a second feature in the description that follows may include embodiments in which the first and second features are formed in direct contact, and may also include embodiments in which the first and second features may not be in direct contact (e.g., additional features may be formed between the first and second features). In addition, for the purposes of simplicity and clarity, the embodiments of the present disclosure may use the same or similar reference numbers for designating the same or similar components in many examples. Drawings may merely show portions of the flash memory of the present invention. The present invention will be described in more detail below with reference to the accompanying drawings.

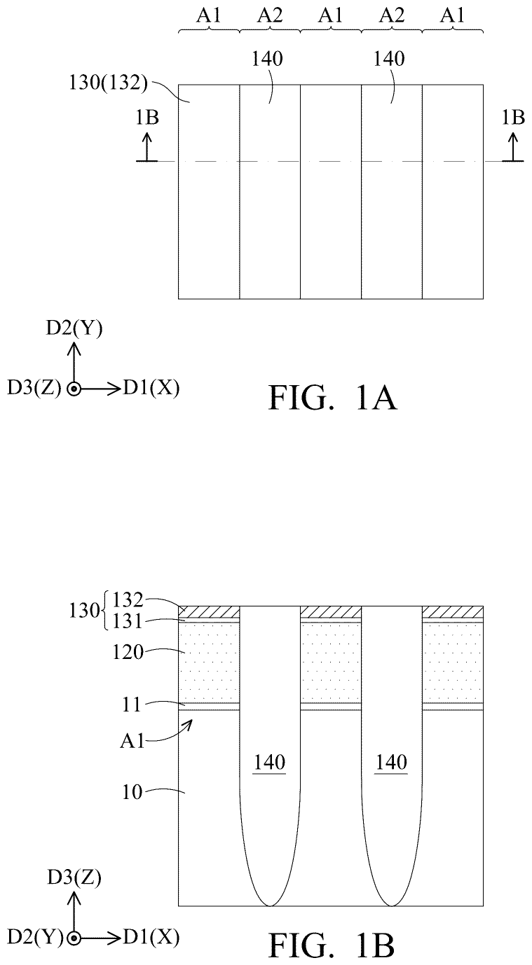

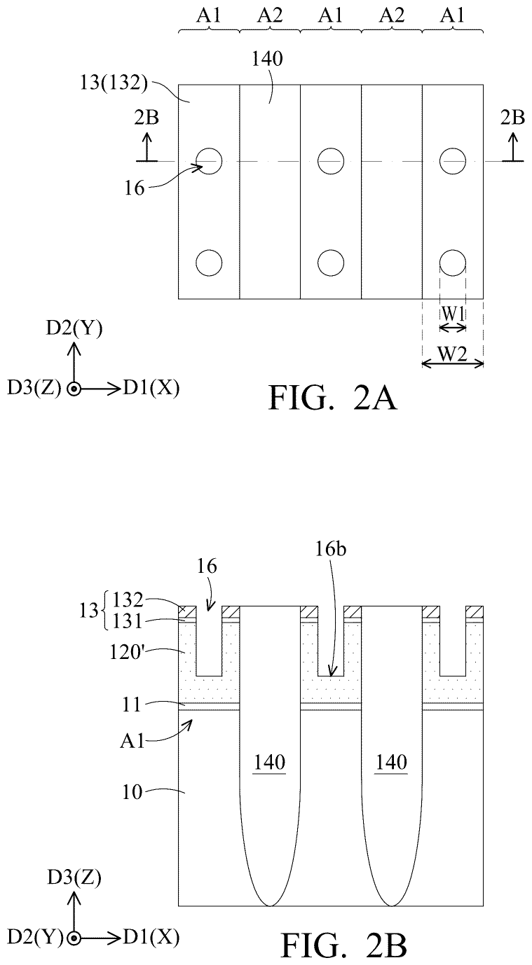

Referring to FIG. 1A and FIG. 1B, several isolation structures 140 that extend in the second direction D2 are formed between the active regions A1 of the substrate 10, in accordance with some embodiments of the present disclosure. The tunneling dielectric layer 11, the first gate material layer 120 and the hard mask 130 that extend in the second direction D2 may be sequentially formed on the substrate 10 (such as stacked in the third direction D3). The isolation structures 140 may separate adjacent first gate material layers 120 from each other. The active region A1 extends, for example, in the first direction D1.

In some embodiments, the substrate 10 may include silicon, gallium arsenide, gallium nitride, germanium silicide, silicon-on-insulator (SOI), another suitable semiconductor material, or a combination thereof. The tunneling dielectric layer 11 may comprise a silicon oxide or one or more high-k (dielectric constant) dielectric constant materials. In some embodiments, the first gate material layer 120 includes polysilicon, another suitable conductive material, or a combination thereof. The hard mask 130 may include an oxide layer 131 and a silicon nitride layer 132 on the oxide layer 131. The oxide layer 131 is, for example, a native oxide layer or a silicon oxide layer. In some exemplary embodiments, the silicon oxide layer is a tetraethyl orthosilicate (TEOS) layer.

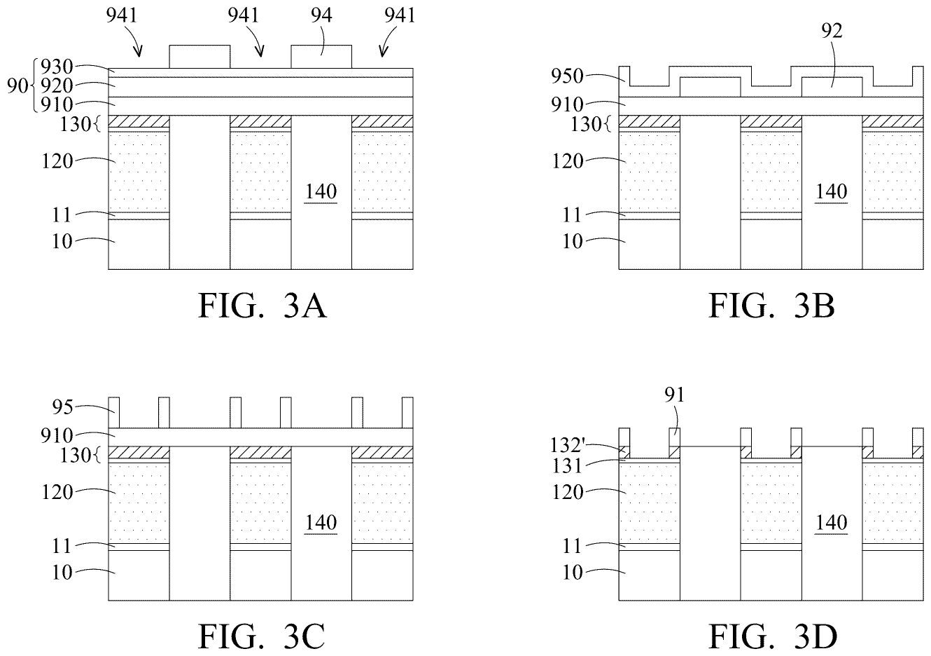

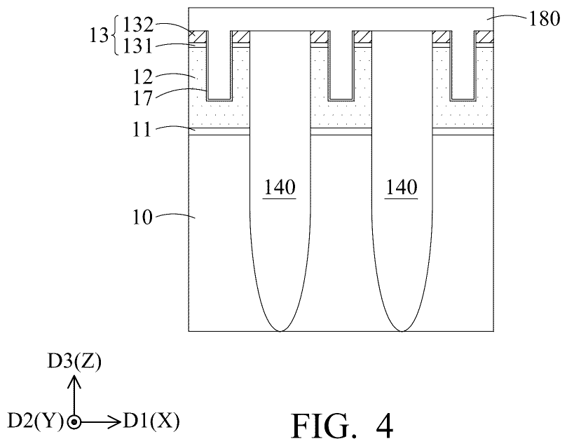

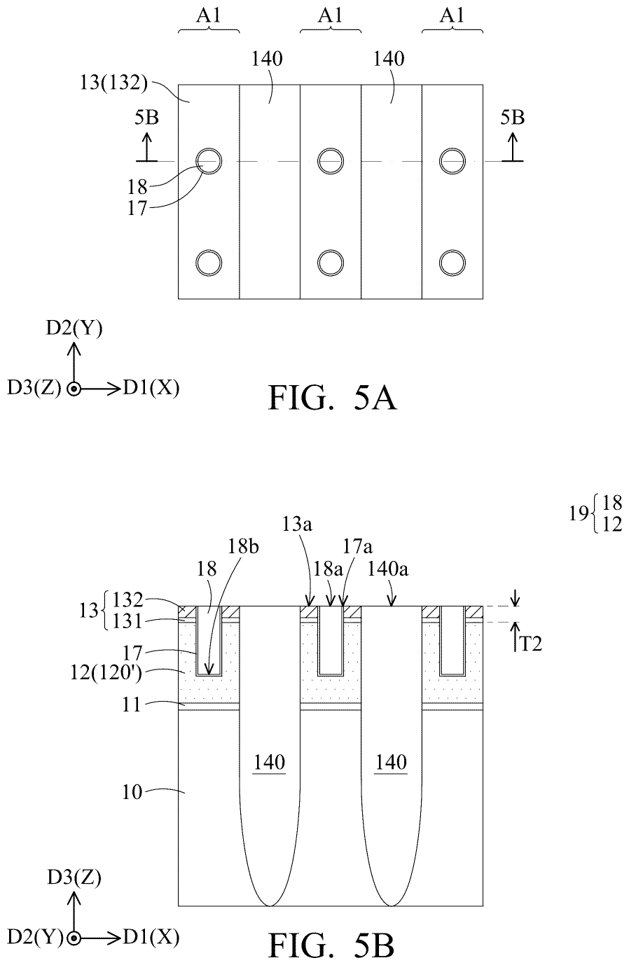

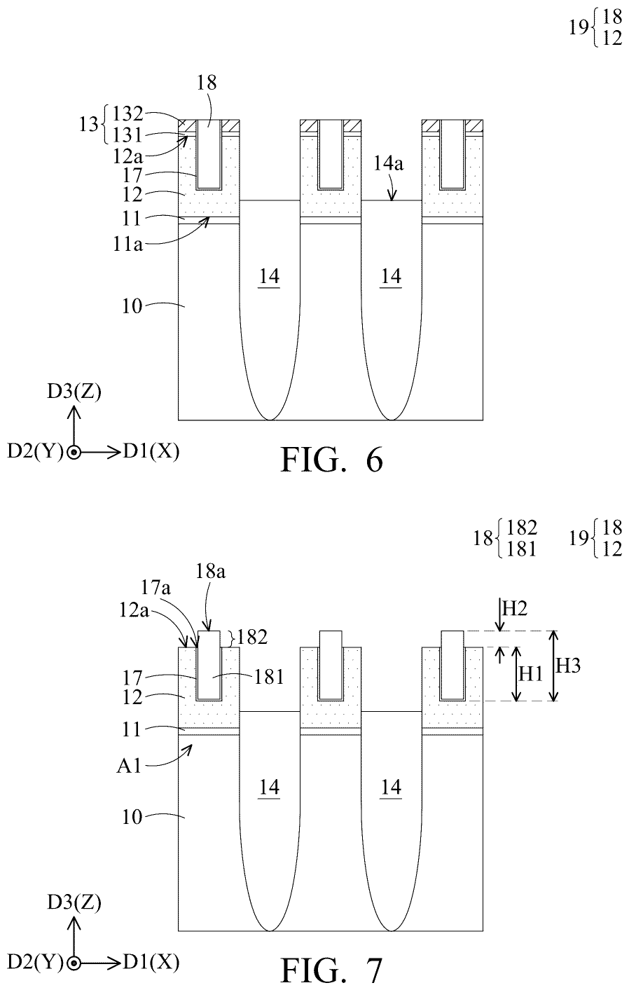

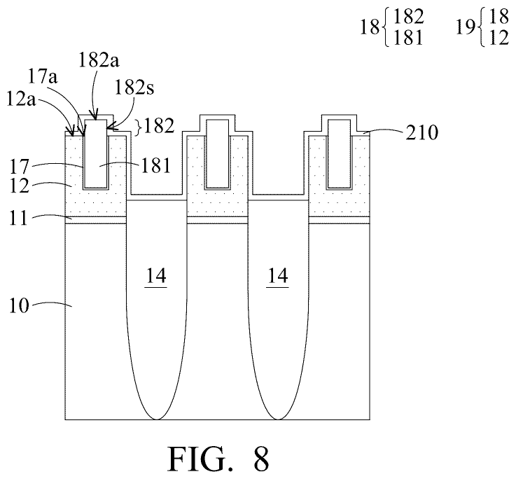

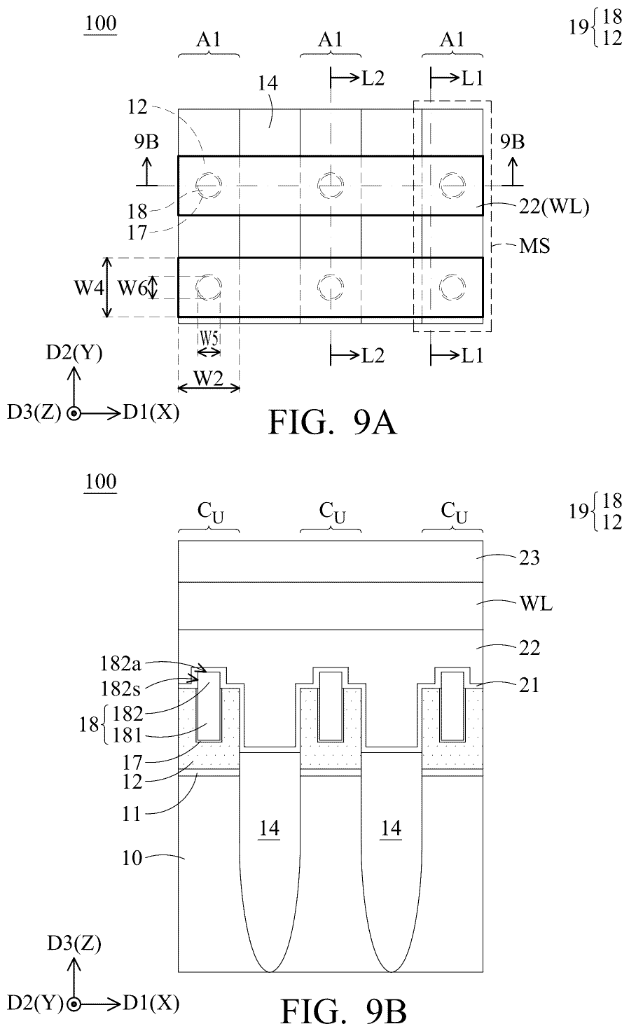

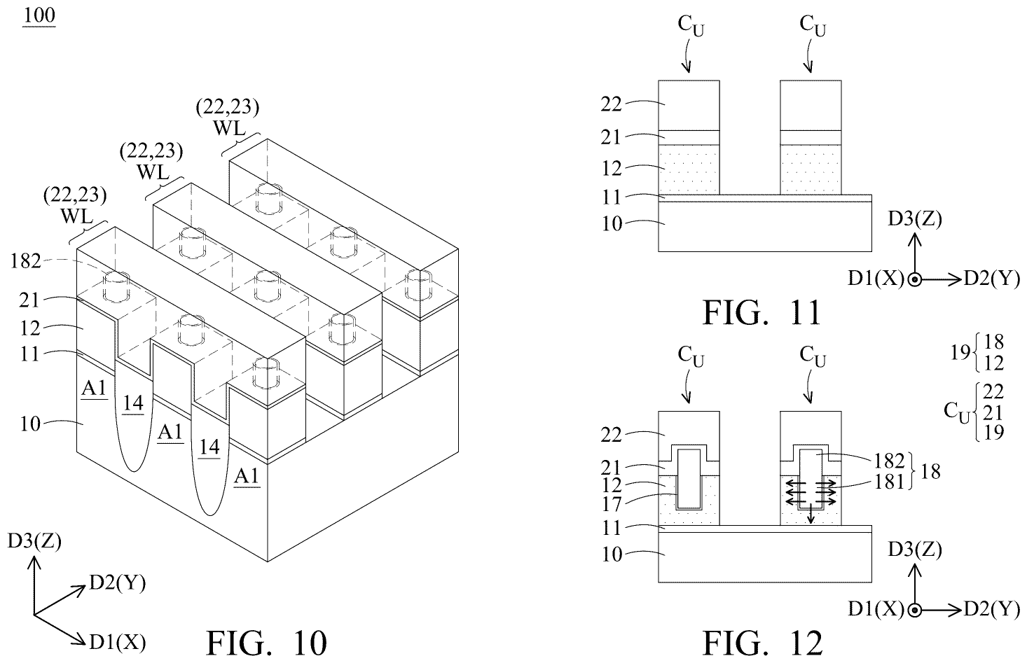

Next, referring to FIG. 2A and FIG. 2B, the hard mask 130 and the first gate material layer 120 are partially removed to form the patterned hard mask 13 and the first gate material layer 120′ having recesses 16, respectively. The first gate material layer 120′ having the recesses 16 may be used to form the first portion 12 of the lower gate electrode 19 in the subsequent processes (FIG. 9B and FIG. 10). The bottom surface 16b of the recess 16 is positioned between the top surface and the bottom surface of the first gate material layer 120′.

In this exemplary embodiment, the dimension of the recess 16 is less than the dimension of the active region A1, and the width of the recess 16 does not exceed the width of the first gate material layer 120′. As shown in FIG. 2A, the width W1 of the recess 16 in the first direction D1 is less than the width W2 of the first gate material layers 120′ in the first direction D1.

In some embodiments, a fine spacer pattern is formed above the first gate material layer 120 by using a resolution enhancement of lithography by assist of chemical shrink (RELACS) process. Then, the hard mask 130 and the first gate material layer 120 are partially etched to form the patterned hard mask 13 and the recesses 16 using the fine spacer pattern.

In addition, as shown in FIG. 3A to FIG. 3D, in accordance with some embodiments of the present disclosure, the aforementioned fine spacer pattern can be formed by a self-aligned process for forming spacers.

Referring to FIG. 3A, a pattern transfer layer 90 is formed on the hard masks 130, and a patterned mask layer 94 is formed above the pattern transfer layer 90, in accordance with some embodiments of the present disclosure. The pattern transfer layer 90 may include a polysilicon layer 910, a carbon-containing layer 920 and an anti-reflective layer 930 that are sequentially formed. The carbon-containing layer 920 includes carbides, for example, diamond-like carbon, an amorphous carbon film, and a highly selective transparent carbon-containing layer. The material of the anti-reflective layer 930 includes, for example, organic polymers, carbon, silicon oxynitride, or another suitable material. The patterned mask layer 94 is, for example, a patterned photoresist layer having openings 941 corresponding to the first gate material layers 120. The polysilicon layer 910, the carbon-containing layer 920, the anti-reflective layer 930 and the patterned mask layer 94 may be formed using any known process.

Next, referring to FIG. 3B, in the present embodiment, the pattern transfer layer 90 is etched (such as by dry etching) using the patterned mask layer 94 as an etch mask to form a patterned carbon-containing layer 92 (also called as a transfer pattern). In this etching process, the polysilicon layer 910 acts as an etch stop layer. Next, the patterned mask layer 94 and the anti-reflective layer 930 are removed. In some embodiments, the patterned mask layer 94 may be removed by an ashing process or another suitable process. Next, a spacer material layer 950 is conformally formed over the polysilicon layer 910 and the patterned carbon-containing layer 92. The spacer material layer 950 may include oxide, for example, a tetraethyl orthosilicate (TEOS) layer.

Next, referring to FIG. 3C, portions of the spacer material layer 950 are removed to form several spacers 95 on the sidewalls of the patterned carbon-containing layer 92. Next, the patterned carbon-containing layer 92 is removed. In this exemplary embodiment, the spacers 95 are on the polysilicon layer 910 and correspond to the edges of the first gate material layers 120. Next, as shown in FIG. 3D, the polysilicon layer 910 is patterned to form a patterned polysilicon layer 91 using the spacers 95 as the fine spacer pattern. Then, the silicon nitride layer 132 is etched using the patterned polysilicon layer 91 as an etching mask to form a patterned silicon nitride layer 132′. In addition, the spacers 95 and the patterned polysilicon layer 91 are removed in the appropriate steps.

It should be noted that other known methods to the skilled person in the art may be used to form the above-mentioned fine spacer pattern. The present invention is not limited to the above methods.

Referring to FIG. 4, after the recesses 16 are formed, a second gate material layer 180 is formed on the patterned hard masks 13, and fills the recesses 16. In some exemplary embodiments, the second gate material layer 180 may include polysilicon, another suitable conductive material, or a combination thereof. The second gate material layer 180 may be formed by any known method or process.

Next, referring to FIG. 5A and FIG. 5B, the excess portion of the second gate material layer 180 is removed using a combination of the patterned hard masks 13 as a stop layer, in accordance with some embodiments of the present disclosure. The remaining portions of the second gate material layer 180 fill the recesses 16, and can be referred to as the second portions 18 of the lower gate electrodes 19 of the embodiments. The excess portion of the second gate material layer 180 can be removed using an etch back process or a planarization process (such as a CMP process), thereby forming the second portions 18 of the lower gate electrodes 19. As shown in FIG. 5B, in some embodiments, the top surfaces 18a of the second portions 18, the top surfaces 13a of the patterned hard masks 13, and the top surfaces 140a of the isolation structures 140 are substantially coplanar.

It should be noted that the first portions 12 and the second portions 18 of the lower gate electrodes 19 may include different materials. In some embodiments, the materials of the first portions 12 and the second portions 18 may include different conductive types of dopants. In some embodiments, the materials of the first portions 12 and the second portions 18 may have different doping concentrations.

According to some exemplary embodiments, one of the first portion 12 and the second portion 18 of the lower gate electrode 19 includes P-type dopants, and the other of the first portion 12 and the second portion 18 includes N-type dopants. Accordingly, when the device is operated, the high voltage is first concentrated in the second portion 18. In some other embodiments, the first portion 12 and the second portion 18 of the lower gate electrode 19 include the dopants that have the same conductivity type, for example, N-type dopants or P-type dopants, but the first portion 12 and the second portion 18 have different doping concentrations. In some embodiments, the first doping concentration of the first portion 12 is less than the second doping concentration of the second portion 18.

In some embodiments, the lower gate electrode 19 is referred to as a floating gate electrode of a flash memory. When the floating gate electrode includes the second portion 18 that has a higher doping concentration, it leads to a higher gate coupling ratio with the subsequently formed inter-gate dielectric layer. Therefore, when a program operation of the flash memory is performed, the high voltage can be concentrated in the second portion 18 first and then dispersed outwardly to the first portion 12 evenly, resulting in a better voltage distribution of the floating gate electrode. Thus, reliability of programming efficiency of the flash memory can be improved.

In some embodiments, the first gate material layer 120 and the second gate material layer 180 can be deposited by high-temperature processes (e.g., in a tube furnace) to form the first gate material layer 120′ and the second portion 18 with uniform doping concentrations, respectively. Next, in the step as shown in FIG. 5B, ion implantation is selectively performed on the top surfaces 18a of the second portions 18 to increase the doping concentration of each of the second portions 18. That is, the doping concentration of the second portion 18 is not limited by the deposition capability of the deposition machine. In this exemplary embodiment, the doping concentration of the second portion 18 is a gradient distribution. For example, the doping concentration of the second portion 18 is decreased from the top surface 18a to the bottom surface 18b. In this regard, since the patterned hard mask 13 cover the top surface of the first gate material layer 120′, only the exposed second portion 18 are subjected to the ion implantation. Thus, the first gate material layer 120′ can be protected from the influence of the aforementioned ion implantation.

In addition, in some embodiments, a high-temperature process can be performed to diffuse the dopants in the second portion 18 to the first portion 12, so that the doping concentration of the first portion 12 is a gradient distribution, for example, the doping concentration inside the first portion 12 decreases as the distance from the second portion 18 increases.

In addition, as shown in FIG. 5B, a barrier layer 17 may be optionally formed between the first portion 12 and the second portion 18 to separate the first portion 12 from the second portion 18, thereby preventing the dopants of the second portion 18 from diffusing into the first portion 12. Therefore, the doping concentration of the second portion 18 can be kept being greater than the doping concentration of the first portion 12 by forming the barrier layer 17. In some exemplary embodiments, after the recesses 16 are formed (FIG. 2A and FIG. 2B), the barrier layer 17 may be formed on the bottom surface and sidewalls of each of the recesses 16 using a plasma treatment (such as a plasma nitriding treatment) or ion implantation (such as nitrogen ion implantation). Accordingly, the second portion 18 is formed on the barrier layer 17, as shown in FIG. 5B. The barrier layer 17 is, for example, a nitrogen-containing layer.

Next, referring to FIG. 6, the isolation structures 140 are recessed to form the isolation portions 14, such that the top surface 14a of the isolation portion 14 is, for example, lower than the top surface of the first portion 12 and higher than the top surface of the tunneling dielectric layer 11, thereby separating the lower gate electrodes 19 on the active regions A1.

Next, referring to FIG. 7, the patterned hard masks 13 are removed to expose the first portions 12 and the second portions 18, in accordance with some embodiments of the present disclosure. In addition, in some embodiments in which the barrier layers 17 are formed, the top surfaces 17a of the barrier layers 17 are exposed after the patterned hard masks 13 are removed. In some embodiments, the second portion 18 is inserted into the first portion 12 of the lower gate electrode 19. The second portion 18 includes a lower part 181 and an upper part 182. The first portion 12 surrounds the lower part 181 of the second portion 18. In addition, the upper part 182 of the second portion 18 protrudes from the top surface 12a of the first portion 12. The barrier layer 17 may be in direct contact with and cover the lower part 181 of the second portion 18 of the lower gate electrode 19.

In addition, although the second portions 18 are depicted as cylinders in the drawings, the present invention is not limited thereto. It should be noted that the shape of the second portion 18 matches the shape of the recess 16. The second portion 18 may be an elliptical pillar, a rectangular pillar, a polygonal pillar, or a pillar that has any cross-sectional shape.

In addition, in some embodiments, the lower part 181 and the upper part 182 of the second portion 18 respectively have a height of H1 and a height of H2. The total height H3 of the second portion 18 is the sum of the height H1 and the height H2. In one exemplary embodiment, the height H1 of the lower part 181 is not less than 50% of the total height H3 of the second portion 18, and not more than 90% of the total height H3 of the second portion 18.

In addition, the height H2 of the upper part 182 of the second portion 18 is equal to the thickness T2 of the patterned hard masks 13 (shown in FIG. 5B), in accordance with some embodiments of the present disclosure. Thus, the protruding height (i.e., the height H2) of the second portion 18 of the lower gate electrode 19 can be controlled by the thickness T2 of the patterned hard masks 13.

Next, referring to FIG. 8, an inter-gate dielectric material layer 210 is blanketly deposited on the lower gate electrode 19, in accordance with some embodiments of the present disclosure. For example, the inter-gate dielectric material layer 210 is conformally deposited on the top surfaces and portions of the sidewalls of the first portions 12, the top surfaces 182a and the protruding sidewalls 182s of the second portions 18 and the recessed isolation portions 14. In addition, in the embodiments that include the barrier layers 17, the inter-gate dielectric material layer 210 also covers the barrier layers 17. For example, the inter-gate dielectric material layer 210 is in direct contact with the top surfaces 17a of the barrier layers 17. In some embodiments, the inter-gate dielectric material layer 210 may be a multi-layered dielectric structure, such as a silicon oxide-silicon nitride-silicon oxide (ONO) layer. The inter-gate dielectric material layer 210 may be formed by any known process.

Next, referring to FIG. 9A and FIG. 9B, another gate material layer (not shown), a word line material layer (not shown) and a hard mask material layer (not shown) are blanketly deposited on the inter-gate dielectric material layer 210 in sequential order. Then, the hard mask material layer, the word line material layer, the gate material layer and the inter-gate dielectric material layer 210 are patterned using suitable patterning processes to form the hard mask layers 23, the word lines WL, the upper gate electrodes 22 and the inter-gate dielectric material layers 21, respectively, over the lower gate electrodes 19. The upper gate electrodes 22 may be referred to as the control gate electrodes of the flash memory. The gate material of the upper gate electrodes 22 may include polysilicon, a metal, a metal silicide or another suitable conductor material. Metal includes, for example, titanium, tantalum, tungsten, aluminum, or zirconium. Metal silicide includes, for example, nickel silicide, titanium silicide, tungsten silicide, or cobalt silicide. In addition, in some exemplary embodiments, the gate material of the upper gate electrodes 22 may include polysilicon and a metallic silicide, such as cobalt silicide, disposed on the polysilicon. The word line material layer may include tungsten or copper. The hard mask material layer may include silicon nitride and oxides.

Next, the subsequent manufacturing processes for forming other known layers or structures, such as forming an interlayer dielectric layer (not shown) and the like, are performed to accomplish the fabrication of the flash memory 100. These known processes are omitted for the sake of simplicity and clarity.

In some embodiments, as shown in FIG. 9A and FIG. 10, the word line WL of the flash memory 100, for example, extends in the first direction D1. And, the word lines WL are separated from each other in the second direction D2. The active region A1 and the isolation portion 14 extend in the second direction D2. The upper gate electrodes 22, the inter-gate dielectric layers 21, the word lines WL, and the hard mask layers 23 are spanned over the alternating active regions A1 and isolation portions 14. Each of the memory cells Cu includes a lower gate electrode 19, an upper gate electrode 22, and an inter-gate dielectric layer 21 between the upper gate electrode 22 and the lower gate electrode 19. The inter-gate dielectric layer 21 covers the upper part 182 of the second portion 18 of the lower gate electrode 19, in accordance with some embodiments of the present disclosure.

Referring to FIG. 9A and FIG. 11, the flash memory 100 includes several memory strings MS over the substrate 10, in accordance with some embodiments of the present disclosure. These memory string MS correspond to the active region A1 and extend in the second direction D2. Adjacent memory strings MS are separated from each other in the first direction D1. In addition, the memory strings MS are separated by the isolation portions 14. The memory string MS includes several memory cells Cu. These memory cells Cu are electrically connected in series in the second direction D2. To simplify the drawings, the hard mask layers 23 and the word lines WL are omitted in FIG. 11.

In some embodiments, as shown in FIG. 9A and FIG. 12, the lower gate electrode 19 includes the first portion 12 and the second portion 18. In addition, the first portion 12 surrounds the lower part 181 of the second portion 18. In some embodiments, the upper part 182 of the second portion 18 protrudes from the top surface of the first portion 12. To simplify the drawings, the hard mask layers 23 and the word lines WL are omitted in FIG. 12.

It should be noted that the second portion 18 of the lower gate electrode 19 is inserted into the first portion 12, in accordance with some embodiments of the present disclosure. The second portion 18 does not extend beyond the active region A1 and the word line WL. As shown in FIG. 9A, the width W5 of the second portion 18 in the first direction D1 is less than the width W2 of the first portion 12 in the first direction D1. The width W6 of the second portion 18 in the second direction D2 is less than the width W4 of the word line WL in the second direction D2. In addition, the width W4 is also the width of the upper gate electrode 22 in the second direction D2, in accordance with some embodiments of the present disclosure.

To further reduce the variation of the threshold voltage of the memory cell Cu, the flash memory 100 of the embodiments has a narrower threshold voltage distribution width. In some exemplary embodiments, the width W5 of the second portion 18 in the first direction D1 is in a range of about 30% to about 70% of the width W2 of the first portion 12 in the first direction D1. In some exemplary embodiments, the width W6 of the second portion 18 in the second direction D2 is, for example, (but not limited to) a range of about 30% to about 70% of the width W4 of the word line WL in the second direction D2.

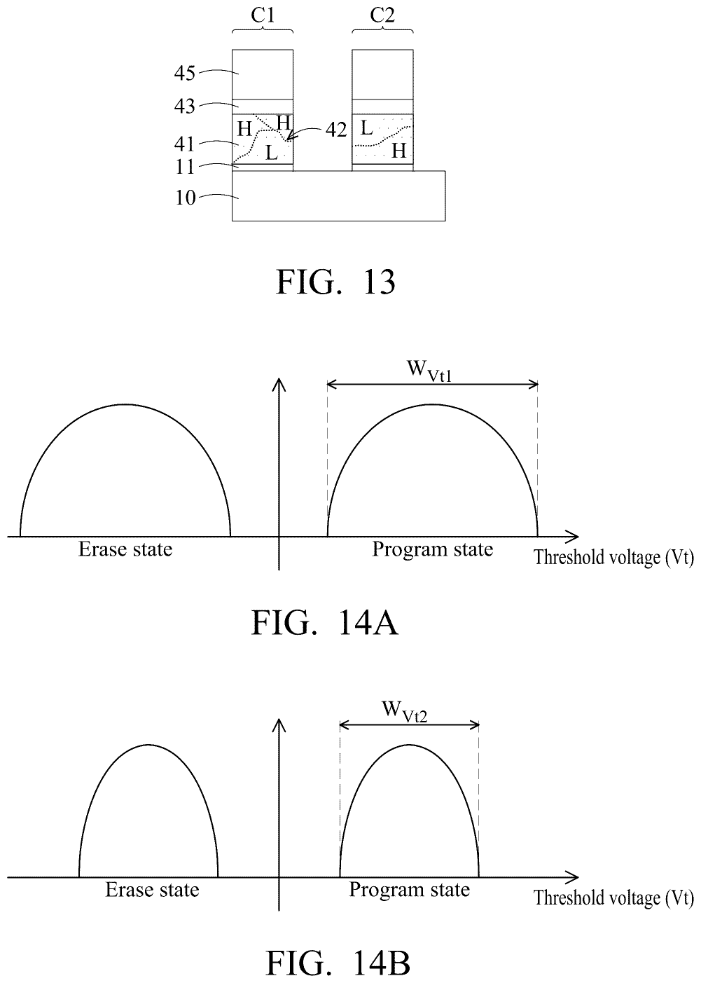

FIG. 13 is a schematic diagram of a cross-section showing memory cells of a conventional flash memory at a position along the same cross-sectional line as that of FIG. 12. Each of the conventional memory cells C1 and C2 includes a lower gate electrode 41, an inter-gate dielectric layer 43 and an upper gate electrode 45. In the conventional memory cells C1 and C2, the lower gate electrode 41 is a continuous block in which grain sizes tend to be different. Thus, the grain boundaries 42 between the grains of the lower gate electrode 41 are presented in a random distribution. When the memory cells C1 and C2 are operated, the randomly distributed grain boundaries 42 has effects on the distribution of the operation voltage in the lower gate electrode 41. For example, some of the grains of the lower gate electrode 41 have higher voltage (labeled as “H” in FIG. 13), and other grains of the lower gate electrode 41 have lower voltage (labeled as “L” in FIG. 13). Therefore, the lower gate electrodes 41 of the conventional memory cells C1 and C2 suffer from the uneven voltage distribution.

In addition, the lower gate electrodes 41 of different memory cells in the same conventional flash memory may have different grain size distribution. For example, the lower gate electrodes 41 of the memory cells C1 and C2 have different grain sizes and different distribution of the grain boundaries 42. That is, the numbers of grains of the lower gate electrodes 41 may be different. In some exemplary embodiments, when the conventional memory cells C1 and C2 are operated, in the lower gate electrode 41 of the memory cell C1, the upper grains have a higher voltage (labeled as “H” in FIG. 13), and the lower grain has a lower voltage (labeled as “L” in FIG. 13). In addition, in the lower gate electrode 41 of the memory cell C2, the upper grain has a lower voltage (labeled as “L” in FIG. 13), and the lower grain has a higher voltage (labeled as “H” in FIG. 13). Accordingly, the lower gate electrodes 41 of neighboring memory cells (such as the memory cells C1 and C2) may have different voltage distributions when the memory cells are operated, which in turn affects the stability and reliability of the threshold voltage during operation.

Referring to FIG. 12, the second portion 18 that is inserted into the first portion 12 may be considered as a plug member of the lower gate electrode 19, in accordance with some embodiments of the present invention. The recesses 16 as shown in FIG. 2A and FIG. 2B provide space for the material deposition and grain formation of the second portion 18. That is, the grains of the second gate material layer 180 that is deposited for fabricating the second portion 18 are confined within the recesses 16. After a heat treatment process is performed, the second gate material layer 180 has homogeneous grain sizes, which reduces the occurrence of randomly distributed grain boundaries 42.

Accordingly, when the memory cell Cu of the embodiment is operated, the operation voltage is first concentrated at the second portion 18 (that has different conductivity type or a higher doping concentration) of the lower gate electrode 19. As described above, compared to the second portion 18, the first portion 12 has a greater volume, and therefore, the number of grain boundaries of the second portion 18 is less than the number of grain boundaries of the first portion 12. As a result, the operation voltage on the second portion 18 of the lower gate electrode 19 can be evenly distributed, and there is no issue of the uneven voltage distribution within the conventional lower gate electrode (such as the lower gate electrode 41 in FIG. 13). According to some embodiments, the operation voltage that is concentrated in the second portion 18 is then evenly distributed to the first portion 12 in all directions, as depicted by the arrows of the memory unit Cu in the right portion of FIG. 12. Thus, when a single memory cell Cu of the embodiment is operated, the voltage on the second portion 18 is evenly distributed.

In addition, according to some embodiments, for different memory cells Cu in the same flash memory that have the same dual-structured lower gate electrodes 19, the second portions 18 of the lower gate electrodes 19 may have the same or a very similar distribution of grain boundaries. Therefore, when the memory cell Cu of the embodiment is operated, different memory cell Cu may also have the same or similar voltage distribution. Thus, the flash memory 100 that is formed by the method of the embodiments has a more stable threshold voltage during operation.

According to the conventional flash memory as shown in FIG. 13, there is a big difference in the threshold voltages whether the flash memory is in a program state or an erase state. Therefore, as shown in FIG. 14A, the conventional flash memory has a greater threshold voltage distribution width Wᵥₜ₁ (i.e., the difference between the maximum threshold voltage and the minimum threshold voltage). In contrast, the flash memory 100 has a smaller threshold voltage distribution width Wᵥₜ₂, in accordance with some embodiments of the present disclosure, whether the flash memory is in a program state or an erase state. Therefore, as shown in FIG. 14B, the flash memory 100 has a narrower threshold voltage distribution width Wᵥₜ₂.

According to the aforementioned descriptions, the flash memory and the method for manufacturing the same, in accordance with some embodiments of the present disclosure, have many advantages. In some embodiments, the second portion that is inserted into the first portion of the lower gate electrode of the flash memory can reduce the threshold voltage distribution width, which in turn increases the reliability of the threshold voltage during operation of the flash memory. For example, the memory cells of the flash memory of the embodiments have better data retention and operation cycles (i.e., the endurance of the flash memory is increased), thereby improving the electrical performance of the flash memory.

In addition, according to some embodiments of the present invention, the upper part of the second portion of the lower gate electrode protrudes from the first portion, such that the inter-gate dielectric layer covers not only the top surface of the first portion, but also the top surface and all the sidewalls of the upper part of the second portion. Compared to a conventional lower gate electrode, the flash memory of the embodiments do increase the contact area between the inter-gate dielectric layer and the lower gate electrode, which in turn increases the gate coupling ratio, reduces the operation voltage and reduces the power loss of the flash memory. In addition, since the memory cell of the flash memory, in accordance with some embodiments of the present disclosure, have lower gate electrodes that include protruding upper parts. Thus, the memory cells of the flash memory each have similar and high gate coupling ratio, thereby improving the reliability of the flash memory. In addition, the method for manufacturing the flash memory, in accordance with some embodiments of the present disclosure, is simple and compatible with existing manufacturing processes, and is suitable for mass production.

In addition, the present invention is suitable for manufacturing miniaturized flash memory to increase the total number of dies on a wafer. Therefore, the present invention decreases the production cost and energy consumption for manufacturing a single integrated circuit (IC) device, and reduces the energy consumption of IC package in the subsequent packaging processes. Accordingly, the carbon emission in the processes for manufacturing the flash memory can be greatly reduced. In addition, the reliability and durability of the flash memory of the embodiments are improved, and the operation voltage and power loss are reduced, so that the embodiment of the present disclosure discloses a green technology in the semiconductor industry.

What is claimed is:

1. A flash memory, comprising:
a substrate, having a plurality of active regions; and
a plurality of memory cells, wherein each of the memory cells comprises a lower gate electrode, an inter-gate dielectric layer on the lower gate electrode and an upper gate electrode on the inter-gate dielectric layer, wherein the lower gate electrode comprises:
a first portion over the substrate; and
a second portion inserted into the first portion, wherein the first portion surrounds a lower part of the second portion, and an upper part of the second portion protrudes from a top surface of the first portion, and the inter-gate dielectric layer covers a top surface and sidewalls of the upper part,
wherein the first portion and the second portion comprise different materials.

2. The flash memory as claimed in claim 1, wherein the first portion has a first doping concentration, the second portion has a second doping concentration, and the second doping concentration is greater than the first doping concentration.

3. The flash memory as claimed in claim 1, wherein dopants of the first portion and the second portion have different conductivity types.

4. The flash memory as claimed in claim 1, wherein each of the memory cells further includes a barrier layer between the first portion and the second portion to separate the lower part of the second portion from the first portion.

5. The flash memory as claimed in claim 4, wherein the inter-gate dielectric layer is in contact with a top surface of the barrier layer.

6. The flash memory as claimed in claim 1, wherein a height of the lower part of the second portion is in a range of 50% to 90% of a total height of the second portion.

7. The flash memory as claimed in claim 1, wherein the upper gate electrode extends in a first direction, each of the active regions extends in a second direction, and the second direction is different from the first direction; and
wherein the second portion of the lower gate electrode is a pillar inserted into the first portion, and a width of the pillar in the first direction is less than a width of the first portion in the first direction.

8. The flash memory as claimed in claim 7, wherein a width of the pillar in the second direction is less than a width of the upper gate electrode in the second direction.

9. The flash memory as claimed in claim 1, wherein the upper gate electrode extends in a first direction, each of the active regions extends in a second direction, and the second direction is different from the first direction; and
wherein the memory cells on the active regions are electrically connected to form a memory string.

10. A method for manufacturing a flash memory, comprising:
providing a substrate having a plurality of active regions; and
forming a plurality of memory cells, wherein each of the memory cells comprises:
a lower gate electrode, an inter-gate dielectric layer on the lower gate electrode and an upper gate electrode on the inter-gate dielectric layer,
wherein forming the lower gate electrode comprises:
forming a first portion over the substrate; and
forming a second portion inserted into the first portion, wherein the first portion surrounds a lower part of the second portion, and an upper part of the second portion protrudes from a top surface of the first portion, and the inter-gate dielectric layer covers a top surface and sidewalls of the upper part,
wherein the first portion and the second portion comprise different materials.

11. The method for manufacturing the flash memory as claimed in claim 10, wherein a doping concentration of the second portion is greater than a doping concentration of the first portion.

12. The method for manufacturing the flash memory as claimed in claim 10, wherein dopants of the first portion and the second portion have different conductivity types.

13. The method for manufacturing the flash memory as claimed in claim 10, wherein forming the lower gate electrode further comprises:
forming a barrier layer between the second portion and the first portion to separate the first portion from the lower part of the second portion.

14. The method for manufacturing the flash memory as claimed in claim 13, wherein the first portion has a recess, and a nitrogen-containing layer is used as the barrier layer that is formed on the bottom surface and sidewalls of the recess, wherein the nitrogen-containing layer is formed by performing a plasma nitriding treatment or nitrogen ion implantation.

15. The method for manufacturing the flash memory as claimed in claim 10, wherein forming the lower gate electrode further comprises:
performing ion implantation on the upper part to implant dopants into the second portion; and
diffusing the dopants.

16. The method for manufacturing the flash memory as claimed in claim 10, wherein forming the lower gate electrode further comprises:
forming a patterned hard mask on a first gate material layer over the active regions;
etching the first gate material layer using the patterned hard mask as an etch mask to remove a portion of the first gate material layer to form a recess, wherein remaining portions of the first gate material layer form the first portion of the lower gate electrode;
forming a second gate material layer on the patterned hard mask and the first portion of the lower gate electrode, wherein the second gate material layer fills the recess;
removing a portion of the second gate material layer on the patterned hard mask to expose a top surface of the patterned hard mask, wherein remaining portions of the second gate material layer form the second portion of the lower gate electrode; and
removing the patterned hard mask.

17. The method for manufacturing the flash memory as claimed in claim 16, wherein a height of the upper part of the second portion protruding from the first portion is the same as a thickness of the patterned hard mask.

18. The method for manufacturing the flash memory as claimed in claim 16, wherein forming the patterned hard mask comprises:
forming a hard mask on the first gate material layer;
forming a pattern transfer layer on the hard mask;
etching the pattern transfer layer to form a transfer pattern;
forming spacers on sidewalls of the transfer pattern, wherein the spacers are positioned above the first gate material layer;
removing the transfer pattern; and
etching a hard mask material layer using the spacers as an etch mask to form the patterned hard mask.
